(19) United States
(12) Patent Application Publication
(10) Pub. No.: US 2013/0003284 A1
(43) Pub. Date: Jan. 3, 2013

(54) ELEVATING DISPLAY LID

(76) Inventors: KEVIN MASSARO, Houston, TX (US); Stacy Wolff, Cypress, TX (US); Jonathan Mendoza, San Francisco, CA (US)

(21) Appl. No.: 13/171,131

(22) Filed: Jun. 28, 2011

(51) Int. Cl. H05K 7/00

(52) U.S. Cl. 361/679.28; 361/679.01

(57) ABSTRACT

Embodiments provide apparatuses and systems including a base and a display lid. The display lid may include a surface engaging portion to elevate the base in response to rotation of the display lid.

### BACKGROUND

Computing devices typically utilize vents and fans to increase airflow over various high temperature components. The vents generally are located such that they do not visually affect the aesthetics of the computing device. Generally this involves having a vent on the bottom of the computing device.

### BRIEF DESCRIPTION OF THE DRAWINGS

FIG. 1 illustrates a perspective view of an apparatus in accordance with the present disclosure;

FIG. 2 illustrates a perspective view of an apparatus in accordance with the present disclosure;

FIG. 3 illustrates a profile view of an apparatus in accordance with the present disclosure;

FIG. 4 illustrates a profile view of an apparatus in accordance with the present disclosure;

FIG. 5 illustrates a segmented view of an apparatus in accordance with the present disclosure;

FIG. 6 illustrates a view of an apparatus in accordance with the present disclosure; and

FIG. 7 illustrates a view of an apparatus in accordance with the present disclosure.

### DETAILED DESCRIPTION

Computing devices such as notebook or netbook computers, among others, utilize airflow to mitigate high temperatures associated with various components. The airflow may be directed from the bottom of the notebook through the housing and then out the side or the back of the computing device. When the computing device is placed on a surface, for example a table, desk, or lap, the air intake can be inhibited. This may lead to inefficient cooling and/or overheating of various components.

In the present disclosure, various systems are described which utilize a display lid to elevate a portion of the computing system while in an open position and lower the portion of the computing system while in a closed position. The elevation may increase air intake. Additionally, the system may provide for increased air exhaust while in both an open and closed position. Various corresponding methods are also described.

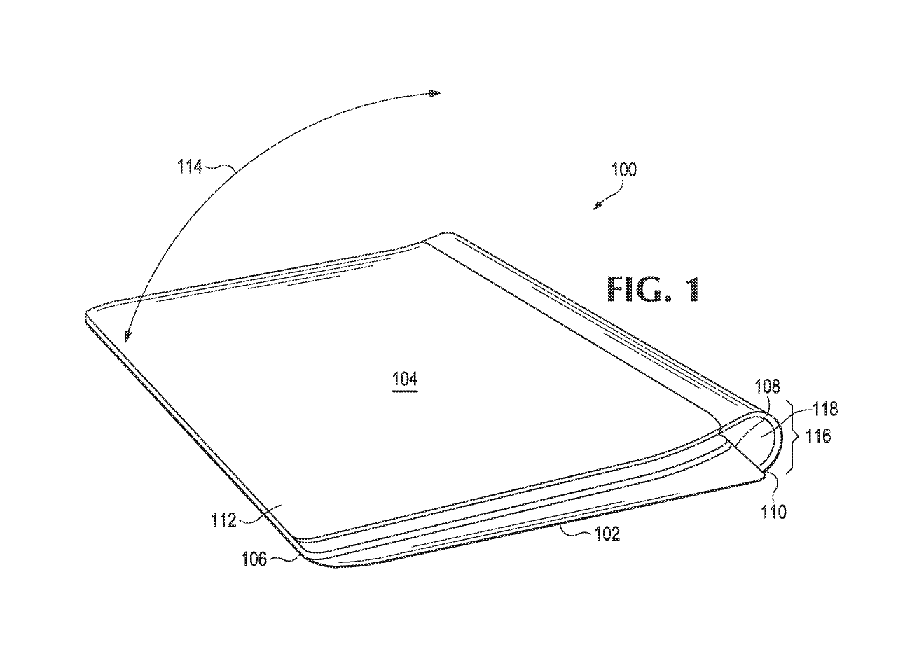

Referring to FIGS. 1 and 2, an example apparatus 100 is illustrated in a closed and open position, respectively. The apparatus 100 includes a base 102 and a display lid 104. The base 102 includes a front end 106 and a back end 108. The display lid 104 includes a first end 110 coupled to the base 102, a second end 112 that pivots about the first end 110, as indicated by arrow 114, and a surface engaging portion 116 disposed between the first end 110 and the second end 112. Other components may be included without deviating from the scope of the disclosure.

In the illustrated example, the apparatus 100 may be a housing for a computing device, such as, but not limited to, a notebook computer, a netbook computer, or any other computing device utilizing a clam-shell like housing in which a display lid is configured to rotate about a pivot point from an open position to a closed position. In the disclosure, an open position is defined as any position in which the second end 112 of the display lid 104 has been rotated out of contact with base 102, as illustrated in FIG. 2. In other words, an open position is one which the display lid 104 and the base 102 form an angle greater than approximately zero degrees. Conversely, a closed position of the apparatus 100 is defined as a position in which the second end 112 of the display lid has been rotated proximate to or into contact with the front end 106 of the base 102, for example, as illustrated in FIG. 1. A closed position may correspond to an angle of zero degrees between the display lid 104 and the base 102.

The apparatus 100 may comprise a variety of materials including various plastics, metals, and other materials generally suitable for housing computing devices. The various materials may be generated in a variety of manners and may include additional materials such as, but not limited to, materials to increase friction (e.g., rubber), materials for grips, and various glosses and/or sealants.

The base 102 of apparatus 100 is configured to house various components including a motherboard, memory, graphics cards, network interface cards, and any other components associated with the computing device. Additionally, the base 102 may comprise various ports and devices such as a keyboard and a touchpad. The base 102 includes a front end 106 which is defined as an end that is closest to a user. A rear end 108 of the base 102 is defined as an end that couples to the display lid 104, and is generally located proximate to a pivot point for the display lid 104. In one example, the rear end of the base 102 may include a hinge to couple to the display lid 104. The base 102 may be configured to engage a surface along a bottom side, and may be elevated from the surface via feet disposed in various predetermined areas.

The display lid 104 of apparatus 100 includes a first end 110 coupled to the base 102, a second end 112 that pivots about the first end 110, and a surface engaging portion 116 disposed between the first end and the second end. The first end 110 is defined as an end configured to couple to base 102 directly, or alternatively, through a hinge. The first end 110 may be configured to route wires or connections from the base 102 to a display housed in the display lid 104. The second end 112 may be a distal end configured to rotate about the first end 110. The second end 112 may include a latch, magnet, or other device configured to interface with the front end 106 of base 102 when the display lid 104 is in a closed position.

The surface engaging portion 116 of the display lid 104 is configured to elevate the base 102 as the second end 112 pivots about the first end 110 (e.g. along arrow 114). The surface engaging portion 116 is disposed on a top side of the display lid 104 and is positioned between the first end 110 and the second end 112. The surface engaging portion 116 may comprise a curved surface to elevate the rear end 108 of the base 102 as the second end 112 of the display lid 104 rotates around the first end 110 of the display lid 104. In another example, the surface engaging portion 116 may include other shapes and/or edges. In the illustrated example, the curved surface of the surface engaging portion 116 may have a substantially constant radius along the curved surface. The substantially constant radius may be configured in a manner such that the curve forms a grip for the hand of a user. In another example, the curved surface may have a radius that varies throughout the surface engaging portion 116, thereby resulting in an oval or out-of-round shape.

Referring to FIG. 1, the apparatus 100 is illustrated in a closed position. The first end 110 of the display lid 104 is coupled to the rear end 108 of the base 102. The second end 112 of the display lid 104 is proximate to the front end 106 of the base 102. The surface engaging portion 116 disposed between the first end 110 and the second end 112 is located on a top side of the display lid 104 and is out of contact with a surface supporting the apparatus 100. In the closed position, the apparatus 100 is level with the surface engaged by the base 102. In the closed position, the area 118 inside of the surface engaging portion 116, when in a closed position, forms a tunnel along a length of the base 102. The area 118 may facilitate exhaust of air from the housing or intake of air into the housing.

Referring to FIG. 2, the apparatus 100 is illustrated in an open position. The first end 110 of the display lid 104 is coupled to the rear end 108 of the base 102. The second end 112 of the display lid 104 is rotated away from the front end 106 of base 102 along arrow 114. The second end 112 is rotated about the first end 110 in a clam-shell like manner. As the display lid 104 rotates about the first end 110, the surface engaging portion 116 of the display lid 104 engages the surface supporting the base 102. As the display lid 104 continues to rotate, a portion of the base 102 may be elevated. In the example, the surface engaging portion 116 is configured to elevate the rear end 108 of the base 102 approximately ten millimeters. The surface engaging portion 116 of the display lid 104 may be configured to elevate the base 102 by other lengths. The elevation may be determined to increase airflow, and/or alternatively, to provide an angle for the base 102 and keyboard of the apparatus 100. An angle may be approximately six degrees with respect to the surface. The angle may be determined based on ergonomic factors, and consequently, other angles are contemplated.

As illustrated in FIG. 2, the apparatus 100 in the open position enables the rear end 108 of the base 102 the ability to exhaust and intake air through a vent. The shape of the surface engaging portion 116 of the display lid 104 may enable a computing system to exhaust air efficiently as the display and the display lid 104 are removed from engagement with the rear end of the apparatus 100. In addition, when the apparatus 100 is in the open position a distance 202 is generated between the base 102 and the display lid 104. This distance 202 may be utilized for various other components such as speakers. That is, the distance 202 may enable speaker placement in manner that allows their directionality to be altered. Other uses are contemplated.

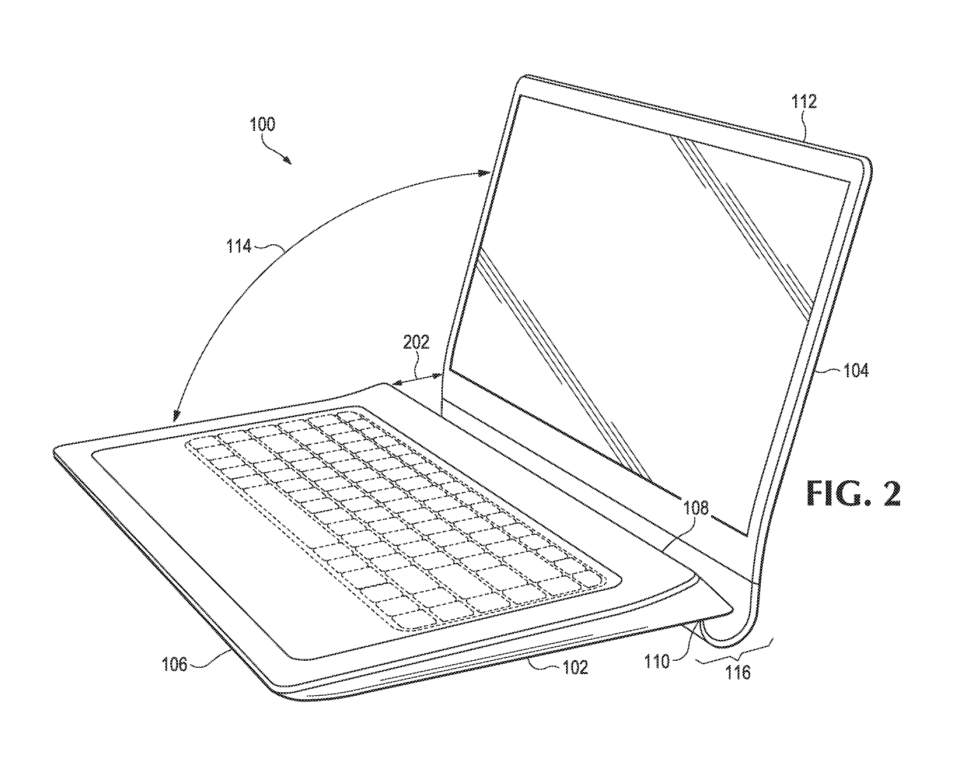

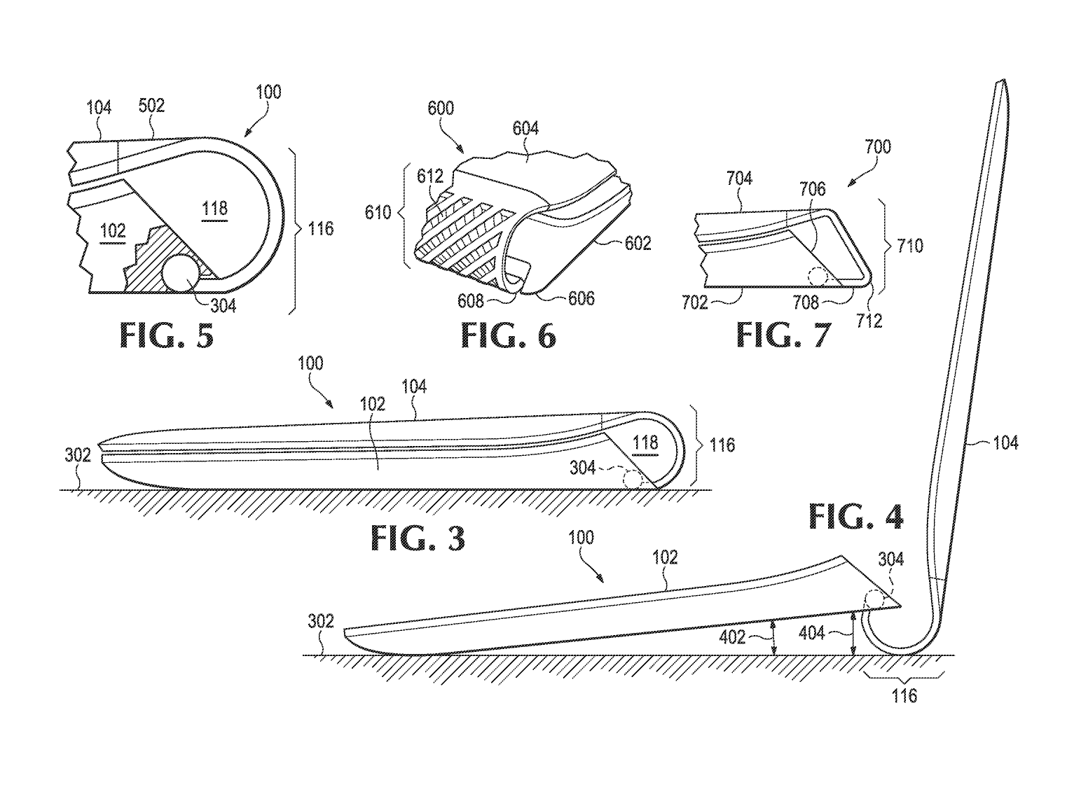

Referring to FIGS. 3 and 4, open and closed profile views of apparatus 100 are illustrated in accordance with the present disclosure, In FIG. 3, apparatus 100 is resting on surface 302 in a closed position. That is, lid 104 has rotated about pivot 304 until coming into contact with base 102. The area 118 inside the surface engaging portion 116 may enable air to pass into and/or out of the base 102.

In FIG. 4, the apparatus 100 is illustrated in an open position. That is, lid 104 has rotated about pivot 304 into an open position. When rotated into the open position, surface engaging portion 116 engages surface 302. As the lid 104 is opened further, various portions of the surface engaging portion 116 engage surface 302 in manner that continually elevates base 102. In one example, surface engaging portion 116 elevates base 102 a distance 404, thereby forming an angle 402 with respect to the surface 302. The angle may be approximately six degrees and the length 404 may be approximately ten millimeters. Other measurements are contemplated.

Referring to FIG. 5, another view of an apparatus 100 is illustrated. The view includes a view of surface engaging portion 116, hinge 304, base 102, display lid 104, and area 118, which may be utilized to direct airflow when the apparatus 100 is in a closed position. In the illustrated example, display lid 104 includes an antenna window 502 for housing an antenna (not illustrated). The antenna window 502 may enable the antenna to be placed in a manner suitable for communication. The antenna window 502 may be include a different material than that of the display lid 104, and consequently, it's placement toward the surface engaging portion 116 may enable a more aesthetic look. In the illustrated example, hinge 304 may be one of multiple hinges. There may be multiple hinges disposed along the length of the base 102.

Referring to FIG. 6, another example is illustrated in accordance with the present disclosure. The apparatus 600 may include components generally similar to those discussed with reference to FIGS. 1-4. Namely, the apparatus 300 may include a base having a front end (not illustrated) and a rear end 606, and a display lid 604 having a first end 608, a second end (not illustrated), and a surface engaging portion 610 disposed between the first end 608 and the second end not illustrated.

In the example, the display lid is coupled to the rear end of the base. In one embodiment, the display lid may be coupled to a bottom side of the rear end 606 of the base 602. Coupling the display lid 604 to the bottom of the rear side 606 of the base 602 may enable the display lid 604 to act as lever to elevate the base 602. In the example, the surface engaging portion 610 of the display lid 604 includes an opening 612 from the top side of the display lid 604 to a bottom side of the display lid 604. As illustrated, the opening 612 may be in the form of a lattice or cross-hatching. The opening or openings 612, may enable airflow exhausted from the base 602 to escape through the display lid 604.

Referring to FIG. 7, another example is illustrated in accordance with the present disclosure. The apparatus 700 may include components generally similar to those discussed with reference to FIGS. 1-4. Namely, the apparatus 700 may include a base 702 having a front end (not illustrated) and a rear end 706, and a display lid 704 having a first end 708, a second end (not illustrated), and a surface engaging portion 710 disposed between the first end 708 and the second end (not illustrated).

In the example, the display lid is coupled to the rear end 708 of the base 702 and configured to act as a pivot about which the second end of the display lid 704 may rotate. In this manner, the display lid 704 may open and dose in a clam-shell like manner to elevate a portion of the base 702. Disposed in between the first end 708 and the second end of the display lid 704 is a surface engaging portion 710. The surface engaging portion 710 is disposed on the top side of the display lid 704. In the illustrated example, the surface engaging portion 710 of the display lid 704 includes an edge 712 to elevate the rear end 706 of the base 702 as the second end of the display lid 704 pivots about the first end 708. The edge 712 is configured to contact the surface and elevate the rear end 702 of the base 702 as the display lid 704 moves from a closed position to an open position. The edge may have a width or alternatively may act as a single point of contact for elevating the base 702.

Although certain embodiments have been illustrated and described herein, it will be appreciated by those of ordinary skill in the art that a wide variety of alternate and/or equivalent embodiments or implementations calculated to achieve the same purposes may be substituted for the embodiments shown and described without departing from the scope of this disclosure. Those with skill in the art will readily appreciate that embodiments may be implemented in a wide variety of ways. This application is intended to cover any adaptations or variations of the embodiments discussed herein. Therefore, it is manifestly intended that embodiments be limited only by the claims and the equivalents thereof.

What is claimed is:

1. An apparatus, comprising:
a base, wherein the base includes a front end and a rear end; and
a display lid, wherein the display lid includes a first end coupled to the base, a second end that pivots about the first end, and a surface engaging portion disposed between the first end and the second end to elevate the base as the second end pivots about the first end.

2. The apparatus of claim 1, wherein the base includes a keyboard.

3. The apparatus of claim 1, wherein the display lid includes a display.

4. The apparatus of claim 1, wherein the surface engaging portion comprises a curved surface to elevate the rear end of the base as the second end pivots about the first end.

5. The apparatus of claim 1, wherein the surface engaging portion comprises an edge to elevate the rear end of the base as the second end pivots about the first end.

6. The apparatus of claim 1, wherein the surface engaging portion comprises a friction inducing material.

7. The apparatus of claim 1, wherein the surface engaging portion is to elevate the rear end of the base approximately six degrees.

8. The apparatus of claim 1, further comprising:
a hinge coupled to a bottom side of the rear end of the base; and
wherein the display lid is coupled to the hinge.

9. The apparatus of claim 1, wherein the surface engaging portion includes an opening from a first side of the display lid to a second side of the display lid.

10. A computing system, comprising:
a base, wherein the base comprises a keyboard; and
a display lid coupled to the base via a hinge, wherein the display lid includes a surface engaging portion disposed between the hinge and a distal end of the display lid, the surface engaging portion to elevate a portion of the base in response to rotation of the display lid to an open position.

11. The computing system of claim 10, wherein the distal end of the display lid is to engage a front end of the base; and
wherein the hinge is coupled to a rear end of the base.

12. The computing system of claim 10, wherein the surface engaging portion comprises a curved surface having a substantially constant radius.

13. The computing system of claim 10, wherein the surface engaging portion comprises an edge.

14. The computing system of claim 10, wherein the portion of the base is elevated approximately ten millimeters from a surface in response to rotation of the display lid to the open position.

15. The computing system of claim 10, wherein the surface engaging portion comprises a friction inducing material.

16. The computing system of claim 15, wherein the friction inducing material is a rubber material.

17. The computing system of claim 10, wherein the hinge is disposed on a bottom side of the base.

18. The computing system of claim 10, wherein the surface engaging portion comprises a hole to increase exhaust from the base.

19. The computing system of claim 10, wherein the hinge is disposed over the surface engaging portion when the display lid is in the open position.

20. The computing system of claim 10, wherein the display lid is to direct airflow in accordance with the surface engaging portion when the display lid is in a closed position.
